(19) United States
(12) Patent Application Publication
(10) Pub. No.: US 2024/0172446 A1
(43) Pub. Date: May 23, 2024

(54) SEMICONDUCTOR DEVICE AND MANUFACTURING METHOD THEREOF, MEMORY AND MEMORY SYSTEM

(71) Applicant: Yangtze Memory Technologies Co., Ltd., Wuhan (CN)

(72) Inventors: Zhaosong LI, Wuhan (CN); Xiaoming MAO, Wuhan (CN); Sizhe LI, Wuhan (CN); Jing GAO, Wuhan (CN); Zongliang HUO, Wuhan (CN)

(73) Assignee: Yangtze Memory Technologies Co., Ltd., Wuhan (CN)

(21) Appl. No.: 18/091,055

(22) Filed: Dec. 29, 2022

(30) Foreign Application Priority Data
Nov. 18, 2022 (CN) 202211449091.8

(51) Int. Cl. H10B 43/35; H10B 43/27

(52) U.S. Cl. CPC H01L 27/1157; H01L 27/11582

(57) ABSTRACT

A semiconductor device includes a stack structure and channel holes penetrating through the stack structure. The stack structure includes alternately stacked dielectric layers and conductive layers, the conductive layers including a top select gate layer. The top select gate layer is provided with a first top select gate isolation structure and a second top select gate isolation structure, and the channel holes are located between the first top select gate isolation structure and the second top select gate isolation structure. The second top select gate isolation structure includes an insulation portion, and the insulation portion is divided into a plurality of second top select gate isolation substructures, so that the critical dimension (CD) of the second top select gate isolation substructure may be matched with the CD of the first top select gate isolation structure.

### CROSS REFERENCE OF RELATED APPLICATIONS

The present application claims the benefit of priority to China Application No. 202211449091.8, “Semiconductor device and manufacturing method thereof, memory and memory system”, file on Nov. 18, 2022, the content of which is incorporated herein by reference in its entirety.

### TECHNICAL FIELD

The present disclosure relates to the field of semiconductor technologies, in particular to a semiconductor device and a manufacturing method thereof, a memory, and a memory system.

### BACKGROUND

Based on its small volume and large capacity, 3D NAND has been used to produce semiconductor devices with high memory density per unit area and highly-efficient memory cell performance by taking the high integration of memory cells stacked layer by layer in a three-dimensional mode as a design concept, which has become the mainstream design in the design and production of emerging semiconductor devices.

In the current 3D NAND structure, the problem about how to pattern is often faced.

### SUMMARY

The present disclosure provides a semiconductor device and a manufacturing, method thereof, a memory, and a memory system, to address the technical problem of patterning TSG Cut for different critical dimensions.

The present disclosure provides a semiconductor device, comprising:
a stack structure including alternately stacked dielectric layers and conductive layers, the conductive layers including a top select gate layer, and
channel holes penetrating through the stack structure;
wherein the top select gate layer is provided with a first top select gate isolation structure and a second top select gate isolation structure, the channel holes being located between the first top select gate isolation structure and the second top select gate isolation structure
the second top select gate isolation structure includes an insulation portion, the insulation portion being divided into a plurality of second top select gate isolation substructures.

In some implementations, the insulation portion of the second top select gate isolation structure is divided in a first direction into a plurality of strip-shaped second top select gate isolation substructures extending in a second direction perpendicular to the first direction.

In some implementations, the plurality of second top select gate isolation substructures are distributed side by side in the first direction, and the plurality of second top select gate isolation substructures have the same dimension in the first direction.

In some implementations, the plurality of second top select gate isolation substructures are distributed side by side in the first direction, and the plurality of second top select gate isolation substructures have different dimensions in the first direction.

In some implementations, the dimensions of the two outermost second top select gate isolation substructures of the plurality of second top select gate isolation substructures distributed side by side in the first direction are different from those of interior second top select gate isolation substructures between the two outermost second top select gate isolation substructures.

In some implementations, the dimensions of the plurality of second top select gate isolation substructures distributed side by side in the first direction increase progressively or decrease progressively in the first direction.

In some implementations, the dimensions of the plurality of second top select gate isolation substructures distributed side by side in the first direction increase progressively or decrease progressively in a direction from the outermost second top select gate isolation substructures to the interior second top select gate isolation substructures.

In some implementations, a plurality of dimensions of the plurality of second top select gate isolation substructures distributed side by side in the first direction are alternately in size in the first direction.

In some implementations, the second top select gate isolation substructure comprises a plurality of segmented structures that are misaligned up and down, left and right to form a plurality of windows.

An implementation of the present disclosure further provides a manufacturing method of the semiconductor device, comprising:
providing a stack layer;
forming alternately stacked dielectric layers and sacrificial layers on the stack layer, and replacing the sacrificial layers with conductive material to form conductive layers;
forming a top select gate layer on the conductive layer at a top of the stack layer, to form a stack structure comprising the dielectric layers, the conductive layers, and the top select gate layer;
forming channel holes penetrating through the stack structure:
enabling the top select gate layer to be formed with a first top select gate isolation structure and a second top select gate isolation structure by using a patterning process, the channel holes being located between the first top select gate isolation structure and the second top select gate isolation structures.
dividing an insulation portion of the second top select gate isolation structure into a plurality of second top select gate isolation substructures by using an etching process; and
filling a conductive substance between two adjacent second top select gate isolation substructures to form a corresponding conductive portion.

In some implementations, the dividing the insulation portion of the second top select gate isolation structure into the plurality of second top select gate isolation substructures comprises:
dividing the insulation portion of the second top select gate isolation structure in a first direction into a plurality of strip-shaped second top select gate isolation substructures extending in a second direction.

In some implementations, the manufacturing method of the semiconductor device further comprises:
dividing the insulation portion into a plurality of strip-shaped second top select gate isolation substructures that are distributed side by side in the first direction and have the same dimension in the first direction.

In some implementations, the manufacturing method of the semiconductor device further comprises:
dividing the insulation portion into a plurality of strip-shaped second top select gate isolation substructures that are distributed side by side in the first direction and have different dimensions in the first direction.

In some implementations, the manufacturing method of the semiconductor device further comprises:
forming the insulation portion to include a plurality of segmented structures that are misaligned up and down, left and right to form a plurality of windows.

In some implementations, the manufacturing method of the semiconductor device further comprises:
removing the conductive substance between the two adjacent strip-shaped second top select gate isolation substructures.

In some implementations, the manufacturing method of the semiconductor device further comprises:
removing the conductive substance through the windows.

An implementation of the present disclosure further provides a memory, which comprises any one of the above semiconductor devices.

An implementation of the present disclosure further provides a memory system, which comprises any one of the above memory and a controller coupled with the memory, the controller being used to control the memory to perform data writing and reading operations.

The present disclosure has the advantageous effect that the insulation portion of the second top select gate isolation structure is divided into a plurality of second top select gate isolation substructures in the manufacturing process, so that the critical dimension (abbreviated as CD) of the second top select gate isolation substructure may be matched with the critical dimension (CD) of the first top select gate isolation structure, so as to avoid the problem of different patterning compensation rules due to the fact that the CD of the first top select gate isolation structure is different from that of the second top select gate isolation structure during mask patterning.

### BRIEF DESCRIPTION OF THE DRAWINGS

In order to more clearly explain the technical solutions in the implementations of the present disclosure, the accompanying drawings required to be used in the description of the implementations will be briefly introduced below. Apparently, the accompanying drawings in the following description are merely some implementations of the present disclosure, those skilled in the art may also obtain other drawings according to these drawings without contributing creative labor.

FIG. 1 is a stereoscopic structural diagram of a semiconductor device provided by an implementation of the present disclosure;

FIG. 2 is a partial structural diagram of FIG. 1 taken along the A1-A1 section;

FIG. 3 is a partial structural diagram of FIG. 1 taken along the XY-axis section;

FIG. 4 is a partial structural diagram of a first structure of FIG. 1 taken along the XY-axis section;

FIG. 5 is a partial structural diagram of a second structure of FIG. 1 taken along the XY-axis section;

FIG. 6 is a partial structural diagram of a third structure of FIG. 1 taken along the XY-axis section;

FIG. 7 is a partial structural diagram of a fourth structure of FIG. 1 taken along the XY-axis section;

FIG. 8 is a partial structural diagram of a fifth structure of FIG. 1 taken along the XY-axis section;

FIG. 9 is a partial structural diagram of a sixth structure of FIG. 1 taken along the XY-axis section;

FIG. 10 is a partial structural diagram of a seventh structure of FIG. 1 taken along the XY-axis section;

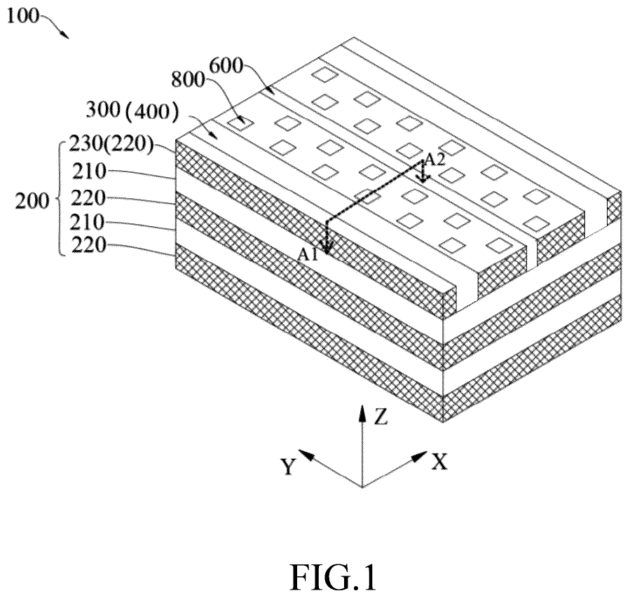

FIG. 1i is a partial structural diagram of an eighth structure of FIG. 1 taken along the XY-axis section;

FIG. 12 is a stereoscopic structural diagram of an unfinished product of manufacturing the semiconductor device shown in FIG. 1 which is provided by an implementation of the present disclosure;

FIG. 13 is a flow chart of a manufacturing method of a semiconductor device provided by an implementation of the present disclosure;

FIG. 14 is a structural diagram of a memory system provided by an implementation of the present disclosure; and

FIG. 15 is a structural diagram of an electronic device provided by an implementation of the present disclosure.

### DETAILED DESCRIPTION

The technical solutions in the implementations of the present disclosure will be clearly and fully described below in conjunction with the figures in the implementations of the present disclosure. Apparently, the described implementations are merely some of the implementations of the present disclosure, not all of the implementations. Based on the implementations of the present disclosure, all other implementations obtained by those skilled in the art without contributing creative labor belong to the scope of protection of the present disclosure.

It should be understood that although the terms “first,” “second,” etc. may be used herein to describe various components, these components should not be limited by these terms. These terms are used to distinguish one component from the other component. For example, a first component may be referred to as a second component, and similarly, a second component may be referred to as a first component, without departing from the scope of the present disclosure.

It will be understood that when one component is referred to as being “on” or “connected to” the other component, it can be directly on or connected to the other component, or intervening components may also be present. Other words used to describe the relationship between components should be interpreted in a similar way.

In the present disclosure, unless stated to the contrary, the used spatial terms such as “up” and “down” usually refer to the up and down in the actual use or working state of a device, specifically the surface direction in the figures; while “inside” and “outside” refer to the outline of the device.

As used in the present disclosure, the term “layer” refers to a material portion including a region with a thickness. A layer has a top side and a bottom side, wherein the bottom side of the layer is relatively close to a substrate, while the top side is relatively far away from the substrate. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive layers and contact layers (in which contacts, interconnect lines are formed) and one or more dielectric layers.

It should be noted that the figures provided in the implementations of the present disclosure only schematically explain the basic conception of the present disclosure. Although only the components associated with the present disclosure are shown in the figures, they are not drawn according to the component number, shape and dimension in an actual implementation. Form, number and proportion of the components in the actual implementation can be arbitrarily changed, and the component layout form may also be more complex.

An NAND flash memory is a non-volatile memory product with low power consumption, light weight and good performance, which has been widely used in electronic products because of its capability of keeping the stored data information in case of power off. A 3D NAND (a three-dimensional memory) is a new type of lash memory, which can further improve memory capacity and reduce memory cost on the basis of two-dimensional NAND flash memories. In the preparation of a current memory device, exemplarily, top select gate cuts (TSG Cut) are formed by an oxide material, so that top select gates (TSG) are separated by the TSG Cuts of a memory area. Moreover, when a memory device is manufactured, a top select gate layer is first formed and several gate line slits (GLS) and channel holes (CH) are formed through the top select gate layer. With the increase of the number of stack structures, it is difficult to completely remove the conductive substance such as polysilicon material at the gate line slits.

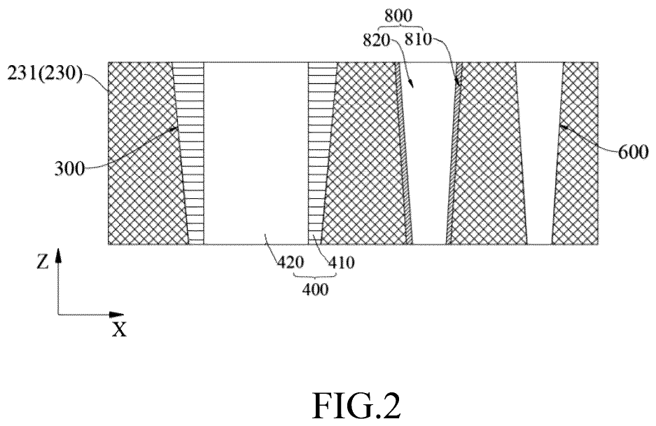

As shown in FIG. 1, a first direction is set as the X-axis direction in the figure, and a second direction is set as the Y-axis direction in the figure. As shown in FIG. 1 and FIG. 2, a top select gate layer 230 is provided with second top select gate isolation structures 400 and first top select gate isolation structures 600 disposed in the first direction, wherein the first top select gate Isolation structures 600 are longitudinally disposed in a stack structure 200 through the top select gate layer 230, the second top select gate isolation structures 400 are longitudinally disposed in the stack structure 200 through the top select gate layer 230.

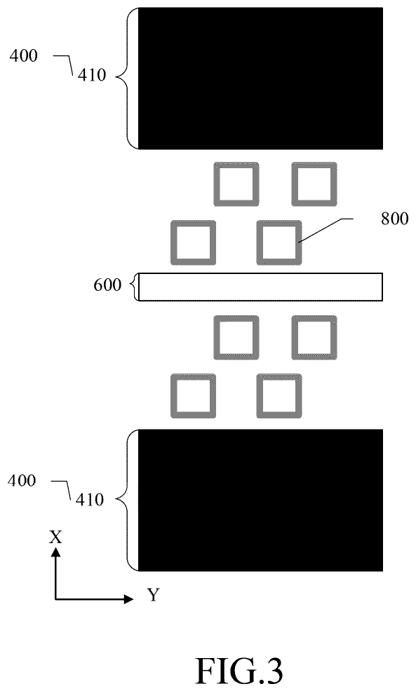

As shown in FIG. 1, FIG. 2 and FIG. 3, the top select gate layer 230 is further provided with a plurality of channel holes 800 longitudinally penetrating through the stack structure 200. The top gate layer 230 comprises a semiconductor material. The channel holes 800 are located between the first top select gate isolation structures 600 and the second top select gate isolation structures 400, that is, one first top select gate isolation structure 600, one channel hole 800 and one second top select gate isolation structure are arranged in sequence.

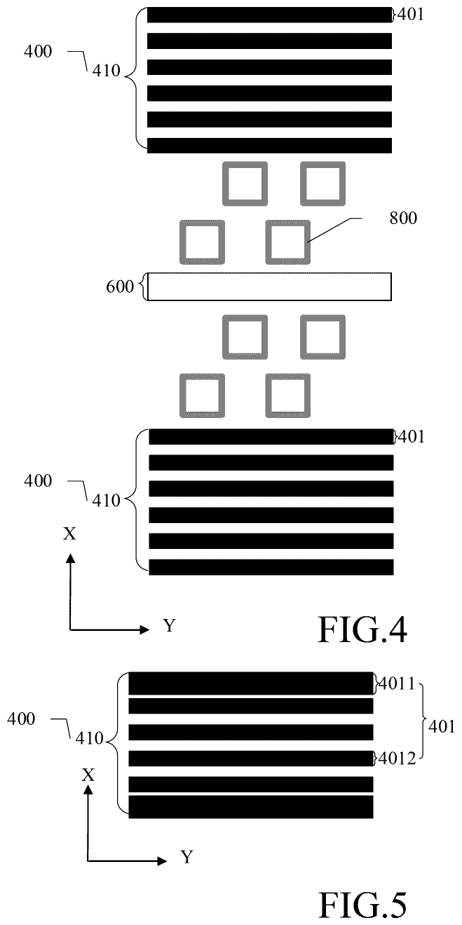

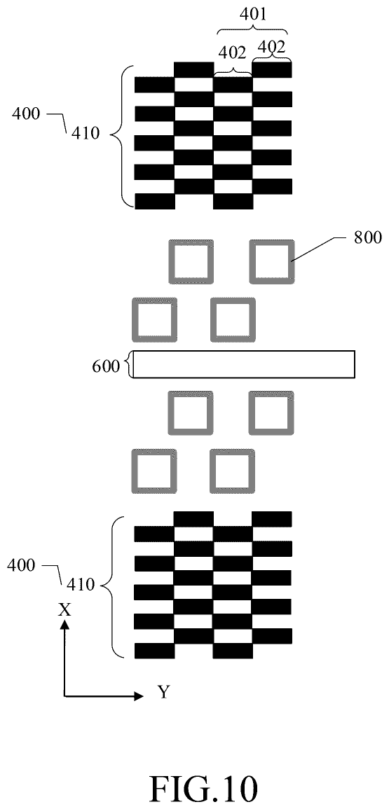

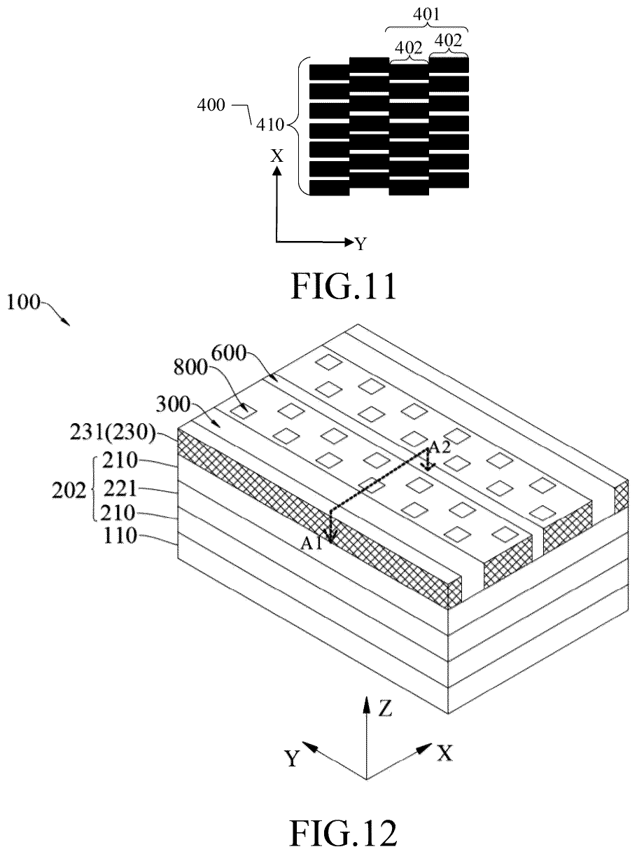

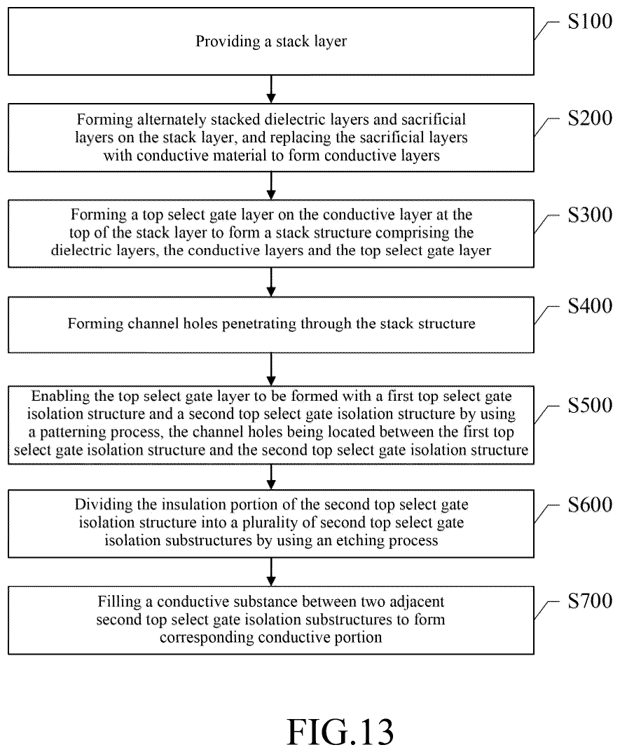

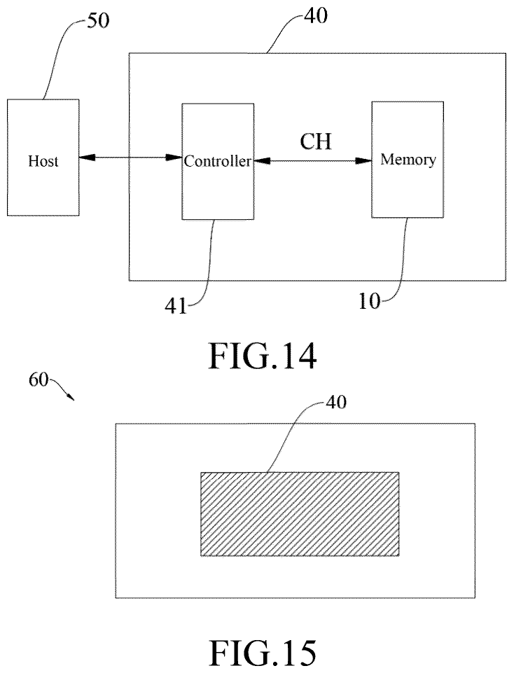

As shown in FIG. 4 to FIG. 11, a gate line slit 300 comprises a second top select gate isolation structure 400, wherein the second top select gate isolation structure 400 comprises an insulation portion 410 within the gate line slit 300 and a conductive portion 420 within the insulation portion 410. The insulation portion 410 is divided into a plurality of second top select gate isolation substructures 401.

Referring to FIG. 1 to FIG. 12, an implementation of the present disclosure provides a semiconductor device 100, comprising:
a stack structure 200 comprising alternately stacked dielectric layers and conductive layers 220, the conductive layer 220 comprising a top select gate layer 230;
channel holes 800 penetrating through the stack structure 200;
wherein the top select gate layer 230 is provided with first top select gate isolation structures 600 and second top select gate isolation structures 400, the channel holes 800 are located between the first top select gate isolation structures 600 and the second top select gate isolation structures 400;
the second top select gate isolation structure 400 comprises an insulation portion 410, the insulation portion 410 is divided into a plurality of second top select gate isolation substructures 401.

As shown in FIG. 1 and FIG. 2, the semiconductor device 100 comprises a stack structure 2(x) that includes dielectric layers 210 and conductive layers 220 extending horizontally and alternately stacked longitudinally. The conductive layers 22t1 comprise a top select gate layer 230 in the stack structure 200. The topmost one of the conductive layers 220 may be the top select gate layer 230, the bottommost one of the conductive layers 2220 may be a bottom select gate layer. The top of the top select gate layer 230 is in a positive direction close to the Z axis, the bottom of the top select gate layer 230 is in a negative direction close to the Z axis.

In the present disclosure, by dividing the insulation portion 410 of the second top select gate isolation structure 400 into a plurality of second top select gate isolation substructures 401 in the manufacturing process, the critical dimension (abbreviated as CD) of the second top select gate isolation substructure 401 may be matched with the critical dimension (CD) of the first top select gate isolation structure W), so as to avoid the problem of different patterning compensation rules due to the fact that the CD of the first top select gate isolation structure 600 is different from that of the second top select gate isolation structure 400 during mask patterning.

The technical solutions of the present disclosure will be described now in conjunction with specific implementations.

In the present implementation, the semiconductor device 100 may be a semiconductor device 100 comprising a substrate, or may be a semiconductor device 100 excluding a substrate.

A conductive portion 420 and an insulation portion 410 are disposed within the second top select gate isolation structure 400. Exemplarily, the second top select gate isolation structure 400 has an inverted trapezoidal shape. A gate line slit has a smaller aperture at a side away from the top of the stack structure 200. Due to factors such as patterning dimensions, errors, etc., the setting amount of the insulation portion 410 within the gate line slit at a side close to the bottom of the stack structure 200 is small. In each manufacturing procedure of the preparation process, it is easy to dig through the insulation portion 410 horizontally, which damages the top select gate layer 230, and reduces the performance of the semiconductor device.

The topmost conductive layer 220 in the stack structure 200 may be the top select gate layer 230, the bottommost conductive layer 220 in the stack structure 200 may be a bottom select gate layer. The top of the top select gate layer 230 is in a positive direction close to the Z axis, the bottom of the top select gate layer 230 is in a negative direction close to the Z axis, the gate line slit 300 is longitudinally disposed in the stack structure 200.

Exemplarily, a material of the conductive layer 220 may be any one of tungsten, cobalt, copper, aluminum, doped silicon, silicide, or combination of any one or more of the above materials. When the top select gate layer 230 comprises a semiconductor material, the gate line slit 300 corresponding to the top select gate layer 230 has a smaller aperture at a side away from the top of the stack structure 200, and the setting amount of the insulation portion 410 in the gate line slit 300 at a side close to the bottom of the stack structure 200 is small. In each manufacturing procedure of the preparation process, it is easy to dig through the insulation portion 410 horizontally, which damages the top select gate layer 230, and reduces the performance of the semiconductor device 100.

The second top select gate isolation structure 400 comprises an insulation portion 410 and a conductive portion 420. The insulation portion 410 is located within the gate line slit 300, and the conductive portion 420 is located within the insulation portion 410. When the gate line slit 300 is formed, the gate line slit 300 is formed into an inverted trapezoidal hole in a top select gate material layer 231 by using a conventional patterning process, the number of the insulation portions 410 in the second top select gate isolation structures is enlarged by using a wet etching process, and the insulation portion 410 is divided in a first direction into a plurality of second top select gate isolation substructures 401 extending in a second direction, that is, the dimension of the insulation portion 410 is reduced, so that more insulation portions 410 may be disposed when the insulation portion 410 is filled subsequently, and even if other manufacturing procedures cause losses to the insulation portions 410, the risk that the insulation portions 410 are dug through horizontally may be reduced.

In some implementations, the dielectric layer 210 is made of an insulation material, including but not limited to any one of silicon nitride, silicon oxide, and aluminum oxide. Here, silicon oxide refers to a silicon oxygen compound such as SixOy, and silicon nitride refers to a nitrogen silicon compound such as SixNy.

Exemplarily, the cross section of the gate line slit 300 corresponding to the top select gate material layer 231 has an inverted trapezoidal shape, that is, the aperture is wide at the top and narrow at the bottom. The bottom of the gate line slit 300 is vulnerable, and the corresponding insulation portion 414) may be easily dug through. However, after the processing of the present disclosure, more insulation portions 410 may be disposed, which increases the wall thickness corresponding to the insulation portion 410, reduces the risk that the insulation portions 410 are dug through horizontally, protects the top select gate layer 230, and improves the performance of the semiconductor device 100.

In some implementations, the semiconductor material of the top select gate layer 230 may be a polysilicon material, including, for example, a monatomic polysilicon material or a doped polysilicon material.

In some implementations, the insulation portion 410 is mainly used for insulation, the insulation portion 410 is made of an insulation material, including but not limited to any one of silicon nitride, silicon oxide, and aluminum oxide. Here, silicon oxide refers to a silicon oxygen compound such as SixOy, and silicon nitride refers to a nitrogen silicon compound such as SixNy.

In some implementations, referring to FIG. 1, FIG. 2, and FIG. 3, the channel holes 800 are located between the first top select gate isolation structures 600 and the second top select gate isolation structures 400.

In some implementations, the channel hole 800 may comprise a channel insulation sub-portion 810 and a channel material sub-portion 820 within the channel insulation sub-portion 810. A material of the channel material sub-portion 820 may be a silicon-based material, and furthermore, may be a polysilicon material, including, for example, a monatomic polysilicon material or a doped polysilicon material. In addition, the material of the channel material sub-portion 820 may further comprise at least one of semiconductor materials such as polycrystalline germanium silicon, silicon carbon, germanium, etc. In some implementations, the channel insulation sub-portion 810 is a composite dielectric layer comprising a tunneling layer, a storage layer (also called a “charge trap/storage layer”), and a blocking layer. The channel hole 800 may have a cylinder shape (e.g., a pillar shape, an inverted trapezoidal shape, etc.). According to some implementations, the channel material sub-portion 820, the tunneling layer, the storage layer, and the blocking layer are radially arranged in this order from the center of the pillar toward the outer surface of the pillar. The tunneling layer may comprise silicon oxide, silicon oxynitride, or any combination thereof. The storage layer may comprise silicon nitride, silicon oxynitride, or any combination thereof. The blocking layer may comprise silicon oxide, silicon oxynitride, high dielectric constant (high-k) dielectric or any combination thereof. In one example, the channel material sub-portion 820 may comprise a composite layer of silicon oxide/silicon oxynitride/silicon oxide (ONO).

In some implementations, the channel insulation sub-portion 810 is made of an insulation material, including but not limited to any one of silicon nitride, silicon oxide and aluminum oxide. Here, silicon oxide refers to a silicon oxygen compound such as SixOy, and silicon nitride refers to a nitrogen silicon compound such as SixNy.

In some implementations, referring to FIG. 1, FIG. 2, and FIG. 3, the insulation portion 410 of the second top select gate isolation structure 400 is divided in a first direction into a plurality of strip-shaped second top select gate isolation substructures 401 extending in a second direction perpendicular to the first direction.

Specifically, the insulation portion 410 of the second top select gate isolation structure 400 as shown in FIG. 3 is divided in a first direction (i.e., the X-axis direction) into a plurality of strip-shaped second top select gate isolation substructures 401 extending in a second direction (i.e., the Y-axis direction) as shown in FIG. 4 to FIG. 10.

In some implementations, referring to FIG. 4, the plurality of second top select gate isolation substructures 401 are distributed side by side in the first direction, and the plurality of second top select gate isolation substructures 401 have the same dimension in the first direction.

In some implementations, the ratio of the dimension of the first top select gate isolation structure 600 to the dimension of the second top select gate isolation structure 400 is 1:7.5 to 1:9. That is, the ratio of the dimension of the second top select gate isolation substructure 401 obtained by dividing the second top select gate isolation structure 400 to the dimension of the first top select gate isolation structure 600 is 1:1. The ratio of the number of the second top select gate isolation substructures 401 obtained by dividing by the second top select gate isolation structure 400 to the number of the first top select gate isolation structures 600 may be 1:7.5 to 1:9.

In some implementations, referring to FIG. 5 to FIG. 10, the plurality of second top select gate isolation substructures 401 are distributed side by side in the first direction, and the plurality of second top select gate isolation substructures 401 have different dimensions in the first direction.

In some implementations, the ratio of the number of the second top select gate isolation substructures 401 obtained by dividing the second top select gate isolation structure 400 to the number of the first top select gate isolation structures 600 is 1:7.5 to 1:9.

In some implementations, the dimensions of the two outermost second top select gate isolation substructures 401 of the plurality of second top select gate isolation substructures 401 distributed side by side in the first direction are different from those of interior second top select gate isolation substructures 401 between the two outermost second top select gate isolation substructures 401.

Specifically, referring to FIG. 5, the dimensions of the two outermost second top select gate isolation substructures 4011 of the second top select gate isolation substructures 401 are greater than those of interior second top select gate isolation substructures 4012 between the two outermost second top select gate isolation substructure 4011. Of course, the dimensions of the two outermost second top select gate isolation substructures 4011 of the second top select gate isolation substructures 401 may be less than those of interior second top select gate isolation substructures 4012 between the two outermost second top select gate isolation substructures 4011, which is also within the scope of protection of the present disclosure.

In some implementations, the dimensions of the plurality of second top select gate isolation substructures 401 distributed side by side in the first direction increase progressively or decrease progressively in the first, direction.

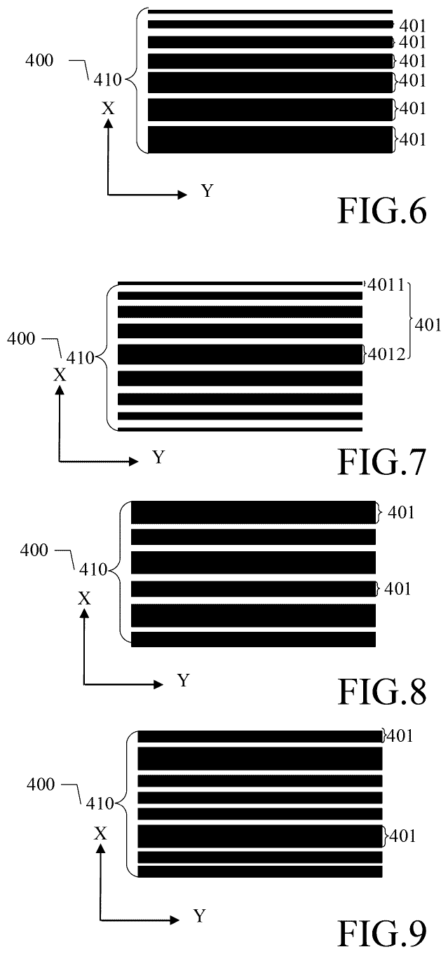

Specifically, referring to FIG. 6, the dimensions of the plurality of second top select gate isolation substructures 401 distributed side by side in the first direction increase progressively in the first direction. Alternatively, the dimensions of the plurality of second top select gate isolation substructures 401 distributed in the first direction, for example, distributed side by side in the first direction decrease progressively in the first direction, which is also within the scope of protection of the present disclosure.

In some implementations, the dimensions of the plurality of second top select gate isolation substructures 401 distributed side by side in the first direction increase progressively or decrease progressively in a direction from the outermost second top select gate isolation substructure 401 to the interior second top select gate isolation substructure 401.

Specifically, referring to FIG. 7, the dimensions of the second top select gate isolation substructures 401 distributed side by side in the first direction increase progressively in a direction from the outermost second top select gate isolation substructure 4011 of the second top select gate isolation substructures 401 to the interior second top select gate isolation substructure 4012. Of course, the dimensions of the second top select gate isolation substructures 401 distributed side by side in the first direction can decrease progressively in a direction from the outermost second top select gate isolation substructure 4011, of the second top select gate isolation substructures 401 to the interior second top select gate isolation substructure 4012, which is also within the scope of protection of the present disclosure.

In some implementations, a plurality of dimensions of the plurality of second top select gate isolation substructures 401 distributed side by side in the first direction are alternately set in the first direction.

Specifically, referring to FIG. 8, the plurality of second top select gate isolation sub structures 401 comprise second top select gate isolation substructures 401 with a first preset, dimension and second top select gate isolation substructures 401 with a second preset dimension, and the second top select gate isolation substructures 401 with a first preset dimension and the second top select gate isolation substructures 401 with a second preset dimension are alternatively disposed. That is, one second top select gate isolation substructure 401 with a second preset dimension is disposed between two adjacent second top select gate isolation substructures 401 with a first preset dimension. Of course, referring to FIG. 9, at least two second top select gate isolation substructures 401 with a second preset dimension can be disposed between two adjacent second top select gate isolation substructures 401 with a first preset dimension.

In the above implementations shown in FIG. 5 to FIG. 9, the ratio of the dimension of the first top select gate isolation structure 600 to the dimension of the second top select gate isolation structure 400 is 1:7.5 to 1:9. That is, the ratio of the dimension of the second top select gate isolation substructure 401 obtained by dividing the second top select gate isolation structure 400 to the dimension of the first top select gate isolation structure 600 is 0.75:1 to 1:1.

In some implementations, the second top select gate isolation substructure 401 comprises a plurality of segmented structures 402, which are misaligned up and down, left and right to form a plurality of windows.

Specifically, each of the second top select gate isolation substructures 401 comprises a plurality of segmented structures 402, which undulate horizontally in the second direction, so that the plurality of segmented structures 402 of two adjacent second top select gate isolation substructures 401 are misaligned up and down, left and right to form a plurality of windows. The undulating shape of the plurality of segmented structures 402 of each of the second top select gate isolation substructures 401 is the same as the undulating trend of distribution of the plurality of channel holes. The plurality of windows formed by misaligning the plurality of segmented structures 402 up and down, left and right are used to remove the filled conductive substances.

Referring to FIG. 12 and FIG. 13, as shown in FIG. 13, an implementation of the present disclosure provides a manufacturing method of the semiconductor device 100, which comprises the following steps S100-S300.

S100: providing a stack layer 2002 as shown in FIG. 12.

Specifically, if the semiconductor device 100 may be a semiconductor device 100 comprising a substrate, a substrate is first provided, the substrate extending in a first direction (X-axis direction) and a second direction (Y-axis direction) to form a substrate surface. As an example, the substrate may be selected according to the actual demand of the device, for example, may comprise a silicon substrate, a germanium (Ge) substrate, a silicon germanium (SiGe) substrate, a silicon on insulator (SOT) substrate, a germanium on insulator (GOT) substrate, or the like. Preferably, in this implementation, the substrate comprises a monocrystalline silicon substrate.

It should be noted that the substrate may be an ion doped substrate, specifically, may be a P-type doped substrate or may be an N-type doped substrate.

In an implementation of the present disclosure, the substrate is a semiconductor substrate. For example, the substrate may be a monocrystalline silicon (Si) substrate, a monocrystalline germanium (Ge) substrate, a silicon on insulator (SOI) substrate, a germanium on insulator (GO) substrate, or the like. The substrate may also be a P-type doped substrate or an N-type doped substrate. A suitable material may be selected as the substrate according to the actual demand, which will not be specifically limited in the present disclosure. Of course, in other implementations, the material of the substrate may also be a semiconductor or compound comprising other elements. For example, the substrate may be a gallium arsenide (GaAs) substrate, an indium phosphide (InP) substrate, a silicon carbide (SiC) substrate, or the like. Furthermore, the substrate has a stack surface that is used to form the stack layer 202.

In an implementation of the present disclosure, a deposition method is selected according to the actual needs to form the stack layer 202 with a multi-layered structure on the stack surface. The deposition method may be chemical vapor deposition (CVD), physical vapor deposition (PVD), plasma-enhanced CVD (PECVD), sputtering, metal-organic chemical vapor deposition (MOCVD), atomic layer deposition (ALD), etc.

S200: forming alternately stacked dielectric layers 210 and sacrificial layers 221 on the stack layer 202, and replacing the sacrificial layers 221 with conductive materials to form conductive layers 220.

In an implementation of the present disclosure, referring to FIG. 12, a substrate 110 is provided, and a stack layer 202 is formed on the substrate 110, The stack layer 202 comprises dielectric layers 210 and sacrificial layers 221 extending horizontally and alternately stacked longitudinally. In some implementations, the substrate 110 may be removed in a subsequent manufacturing procedure or may be retained to form a substrate, which is not specifically defined here.

In some implementations, the sacrificial layers 221 are used to form conductive layers 220 after being replaced by conductive materials, and the conductive layers 220 formed after being replaced by conductive materials do not include the top select gate layer 230 subsequently formed. The conductive layers 220 formed after being replaced by conductive materials, the top select gate layer 230, and the dielectric layers 210 form the stack structure 200 as shown in FIG. 1. The stack structure 200 comprises the dielectric layers 210 and the conductive layers 220 extending horizontally and alternately stacked longitudinally, and the conductive layer 220 at the top of the stack structure 200 comprises the top select gate layer 230.

S300: forming a top select gate layer 230 on the conductive layer 220 at the top of the stack layer to form a stack structure comprising the dielectric layers 210, the conductive layers 220, and the top select gate layer 230.

In an implementation of the present disclosure, a top select gate material layer 231 is deposited on the top conductive layer 220 in the stack layer 202 to obtain the top select gate layer 230. In some implementations, the top select gate material layer 231 comprises a semiconductor material, which may be monocrystal line silicon, silicon germanium (SiGe), gallium arsenide (GaAs), germanium (Ge), silicon on insulator (SOI), polysilicon material, etc., For example, the polysilicon material comprises a monatomic polysilicon material or a doped polysilicon material.

S400: forming channel holes penetrating through the stack structure 200.

In an implementation of the present disclosure, before etching the stack structure 200 to form channel holes penetrating through the stack structure 200, a patterned first mask layer (not shown in the figure) is formed on the surface of the stack structure 200 facing away from the substrate, to form openings corresponding to the channel holes in the patterned first mask layer. The positions of the channel holes to be etched in the subsequent etching process are exposed by the openings, that is, the vertical projections of the openings on the surface of the stack structure 200 facing away from the substrate may be at least substantially overlapped with the positions of the channel holes. By disposing the first mask layer, the etching positions of the channel holes can be quickly and accurately determined, so as to etch the stack structure 200.

As shown in FIG. 3, specifically, after the positions of the channel holes are exposed, an appropriate etching process, for example, dry etching or wet etching, is performed to remove parts of the stack structure 200 exposed by the openings to form the channel holes until the substrate is exposed by the channel holes formed by etching. In other words, the channel holes are through holes penetrating through the stack structure 200, which are a part of the channel holes that are finally used to form memory cell strings. The channel holes extend from the surface of the stack structure 200 facing away from the substrate to the stack surface of the substrate to expose the substrate, and a part of channel holes is located in the substrate but does not, penetrate through the substrate. After the channel holes are formed, the first mask layer may be removed.

It should be noted that a plurality of channel holes may be formed on the stack structure 200 simultaneously, that is, the first mask layer may be formed with a plurality of openings respectively corresponding to the plurality of channel holes, and the positions of the plurality of openings correspond to the positions of the plurality of channel holes subsequently formed. In an implementation of the present disclosure, the number, dimension and arrangement of the channel holes are not specifically limited. That is, the channel holes shown in FIG. 1 and FIG. 3 are only used as examples, and are not used to limit the positions and number of channel holes.

In a specific implementation scenario, the channel holes are formed by using a plasma dry etching. During the etching process, with the increase of the channel depth, plasmas entering the bottom of the channel will decrease, the deeper the channel, the less the plasmas, and the slower the corresponding etching rate, so that the resulting channel holes present an inverted trapezoidal channel sidewall structure with a small bottom aperture and a larger top aperture than the bottom aperture.

Of course, in other implementations, the gradient of the sidewall of the channel hole may also be adjusted by adjusting etching process parameters or adopting high aspect ratio etching process, etc., which is not specifically limited in the present disclosure.

S500: enabling the top select gate layer to be formed with first top select gate isolation structures and second top select gate isolation structures by using a patterning process, the channel holes being located between the first top select gate isolation structures and the second top select gate isolation structures.

In an implementation of the present disclosure, before etching the stack structure 200 on one side of the channel holes to form first top select gate isolation structures penetrating through the top select gate layer 230, a patterned second mask layer (not shown) and a patterned third mask layer (not shown) are formed on the surface of the top select gate layer 230 facing away from the substrate, to form openings corresponding to the first top select gate isolation structures in the patterned second mask layer. The positions of the first top select gate isolation structures to be etched in the subsequent etching process are exposed by the openings, that is, the vertical projections of the openings on the surface of the top select gate layer 230 facing away from the substrate may be at least substantially overlapped with the positions of the first top select gate isolation structures. By disposing the second mask layer, the etching positions of the rust top select gate isolation structures can be quickly and accurately determined, so as to etch the top select gate layer 230. Similarly, openings corresponding to the second top select gate isolation structures are formed in the patterned third mask layer, and the positions of the second top select gate isolation structures to be etched in the subsequent etching process are exposed by the openings, that is, the vertical projections of the openings on the surface of the top select gate layer 230 facing away from the substrate may be at least substantially overlapped with the positions of the second top select gate isolation structures. By disposing the third mask layer, the etching positions of the second top select gate isolation structures can be quickly and accurately determined, so as to etch the top select gate layer 230.

Specifically, after the positions of the first top select gate isolation structures are exposed, an appropriate etching process, for example, dry etching or wet etching, is performed to remove parts of the top select gate layer 230 exposed by the openings to form the first top select gate isolation structures, until the dielectric layer 210 closest to the top conductive layer 220 is exposed by the first top select gate isolation structures formed by etching. In other words, the first top select gate isolation structures are through holes penetrating through the top select gate layer 230, which are a part of the gate line slits finally used to divide a core area of a three-dimensional memory into a plurality of memory blocks and/or memory ringers. The first top select gate isolation structures extend from the surface of the top conductive layer 220 in the stack structure 200 facing away from the substrate to the surface of the dielectric layer 210 closest to the top conductive layer 220 facing away from the substrate, and a part of the first top select gate isolation structures is located in the top select gate layer 230 but does not penetrate through the top select gate layer 230. After the First top select gate isolation structures are formed, the second mask layer may be removed.

Specifically, after the positions of the second top select gate isolation structures exposed, an appropriate etching process, for example, dry etching or wet etching, is performed to remove parts of the top select gate layer 230 exposed by the openings to form the second top select gate isolation structures, until the dielectric layer 210 closest to the top conductive layer 220 is exposed by the second top select gate isolation structures formed by etching. In other words, the second top select gate isolation structures are through holes penetrating through the top select gate layer 230, the conductive substance such as polysilicon material filled in the conductive portions at the positions of the second top select gate isolation structures 400 is removed, so that the etching process of the second top select gate isolation structures 400 is easier to operate. The second top select gate isolation structures extend from the surface of the top conductive layer 220 in the stack structure 200 facing away from the substrate to the surface of the dielectric layer 210 closest to the top conductive layer 220 facing away from the substrate, and a part of the second top select gate isolation structures is located in the top select gate layer 230 but does not penetrate through the top select gate layer 230. After the second top select gate isolation structures are formed, the third mask layer may be removed.

It should be noted that a plurality of channel holes may be formed simultaneously, that is, the first mask layer may be formed with a plurality of openings respectively corresponding to the plurality of channel holes, and the positions of the plurality of openings correspond to the positions of the plurality of channel holes subsequently formed. A plurality of first top select gate isolation structures may be formed simultaneously, that is, the second mask layer may be formed with a plurality of openings respectively corresponding to the plurality of first top select gate isolation structures, and the positions of the plurality of openings correspond to the positions of the plurality of first top select gate isolation structures subsequently formed A plurality of second top select gate isolation structures may be formed simultaneously, that is, the third mask layer may be formed with a plurality of openings respectively corresponding to the plurality of second top select gate isolation structures, and the positions of the plurality of openings correspond to the positions of the plurality of second top select gate isolation structures subsequently formed. In an implementation of the present disclosure, the number, dimension and arrangement of the channel holes, the first top select gate isolation structures, and the second top select gate isolation structures are not specifically limited. That is, the channel holes, the first top select gate isolation structures, and the second top select gate isolation structures shown in FIG. 3 are only used as examples, and are not used to limit the positions and number of the first top select gate isolation structures.

In some implementations, an insulation portion 410 and a conductive portion 420 within the insulation portion 410 are filled within the gate line slit 300 to form a second top select gate isolation structure 400. The projection of the gate line slit 300 is overlapped with the projection of the second top select gate isolation structure 400. An insulation portion 410 is filled within the gate line slit 300, and a conductive portion 420 is formed within a recess of the insulation portion 410.

In a specific implementation scenario, the first top select gate isolation structures are formed by using a plasma dry etching. During the etching process, with the increase of the channel depth, plasmas entering the bottom of the channel will decrease, the deeper the channel, the less the plasmas, and the slower the corresponding etching rate, so that the resulting first top select gate isolation structures present an inverted trapezoidal channel sidewall structure with a small bottom aperture and a larger top aperture than the bottom aperture.

Of course, in other implementations, the gradient of the sidewall of the first top select gate isolation structure may also be adjusted by adjusting etching process parameters or adopting high aspect ratio etching process, etc., which is not specifically limited in the present disclosure.

S600: dividing the insulation portion 410 of the second top select gate isolation structure into a plurality of second top select gate isolation substructures 401 by using an etching process.

Specifically, after the position of the insulation portion 410 of the first top select gate isolation structure is exposed, an appropriate etching process, for example, dry etching or wet etching, is performed to remove the parts of the insulation portion 410 exposed by the openings to form a plurality of second top select gate isolation substructures 401.

In some implementations, the forming process of the insulation portion 410 may be a deposition process.

In some implementations, the insulation portion 410 is made of an insulation material, including but not limited to any one of silicon nitride, silicon oxide, and aluminum oxide. Here, silicon oxide refers to a silicon oxygen compound such as SixOy, and silicon nitride refers to a nitrogen silicon compound such as SixNy.

S700: filling a conductive substance between two adjacent second top select gate isolation substructures 401 to form corresponding conductive portion.

Specifically, as shown in FIG. 4, a conductive material such as polysilicon material is deposited and filled in a trench between two adjacent second top select gate isolation substructures 401 to form corresponding conductive portion, to obtain the semiconductor device 100 shown in FIG. 1 and FIG. 3 to FIG. 9.

In some implementations, the etching solution used in the wet etching process may be any one of HF, Cl₂/HF, ADMJHF, and HCl, wherein ADM represents aqueous ammonia, “/” represents combination, for example, “C₁₋₂/HF” represents combination of C₁₋₂ and HF.

In the present disclosure, by dividing the insulation portion 410 of the second top select gate isolation structure 400 into a plurality of second top select gate isolation substructures 401 in the manufacturing process, the critical dimension (abbreviated as CD) of the second top select gate isolation substructure 401 may be matched with the critical dimension (CD) of the first top select gate isolation structure 600, so as to avoid the problem of different patterning compensation rules due to the fact that the CD of the first top select gate isolation structure 600 is different from that of the second top select gate isolation structure 400 during mask patterning.

In some implementations, referring to FIG. 2, the dividing the insulation portion 410 of the second top select gate isolation structure 400 into a plurality of second top select gate isolation substructures 401 comprises:

S610: dividing the insulation portion 410 of the second top select gate isolation structure 400 in a first direction into a plurality of strip-shaped second top select gate isolation substructures 401 extending in a second direction.

In some implementations, referring to FIG. 3 and FIG. 4, S610 of dividing the insulation portion 410 of the second top select gate isolation structure 400 in the first direction into a plurality of strip-shaped second top select gate isolation substructures 401 extending in the second direction comprises:

S611: dividing the insulation portion 410 into a plurality of strip-shaped second top select gate isolation substructures 401 that are distributed side by side in the first direction and have the same dimension in the first direction.

In some implementations, referring to FIG. 3 and FIG. 5 to FIG. 9, S610 of dividing the insulation portion 410 of the second top select gate isolation structure 400 in the first direction into a plurality of strip-shaped second top select gate isolation substructures 401 extending in the second direction comprises:

S612: dividing the insulation portion 410 into a plurality of strip-shaped second top select gate isolation substructures 401 that are distributed side by side in the first direction and have different dimensions in the first direction.

In the present disclosure, the insulation portion 410 of the second top select gate isolation structure 400 is divided into a plurality of strip-shaped second top select gate isolation substructures 401 with different dimensions by a mask layer. The plurality of strip-shaped second select gate isolation substructures 401 may be designed to have dimensions in equal proportion, or may be designed to have dimensions in unequal proportion.

In some implementations, referring to FIG. 3 and FIG. 10 to FIG. 11, the dividing the insulation portion 410 of the second top select gate isolation structure 400 into a plurality of second top select gate isolation substructures 410 comprises:

S620: forming the insulation portion 410 to include a plurality of segmented structures 402 that are misaligned up and down, left and right to form a plurality of windows.

In the present disclosure, the insulation portion 410 of the second top select gate isolation structure 400 is divided into a plurality of segmented structures 402 by a mask layer, and the segmented structures 402 are misaligned up and down, left and right to form a plurality of windows. In this way, the design of the undulating shape of the plurality of segmented structures 402 that are misaligned up and down, left and right is more conducive to the removal of the polysilicon material, and expansion of the CD of the insulation portion 410 is reduced. The plurality of segmented structures 402 are misaligned up and down, left and right to form a plurality of windows, which can form smaller square grooves respectively isolated, so that the polysilicon material Filled in the windows can be subsequently removed from four surfaces, namely, up, down, left, and right.

An implementation of the present disclosure further provides a memory. The memory comprises a memory chip and a peripheral circuit chip. The peripheral circuit chip is electrically connected with the memory chip, and the peripheral circuit chip can store data in the memory chip or read data from the memory chip, wherein the memory chip and/or the peripheral circuit chip may comprise the semiconductor device 100 in any one of the above implementations.

Specifically, the memory 10 may be a three-dimensional memory (e.g., a 3D NAND memory). It can be understood that the memory provided by the implementation of the present disclosure has the same beneficial effects as the above-mentioned semiconductor device because of being provided with the semiconductor device provided by the implementations of the present disclosure.

Referring to FIG. 14, an implementation of the present disclosure further provides a memory system 40. The memory system 40 comprises a controller 41 and the memory 10 in any one of the above implementations. The controller 41 is coupled to the memory 10 and used for controlling the memory 10 to store data.

Specifically, the controller 41 may control the memory 10 through the channel holes 800, and the memory 10 may perform operations based on controlling of the controller 41 in response to a request from the host 50. The memory 10 can receive a command CMD and an Address ADDR from the controller 41 through the channel holes 800 and access an area selected from a memory cell array in response to the address. In other words, the memory 10 can perform an internal operation corresponding to the command on the area selected by the address.

In some implementations, the memory system 40 may be implemented as, for example, a universal flash memory (UFS) device, a solid-state disk (SSD), a multimedia card (MMC, eMMC, RS-MMC, mini-MMC), a secure digital card (SD, mini-SD, microSD), a personal computer memory card international association (PCMCIA) card type of storage device, a peripheral component interconnect (PCI) type of storage device, a PCI-Express (PCI-F) type of storage device, a compact flash (CE) card, a smart media card, a memory stick, etc.

Specifically, the memory system 40 can be used in a terminal product such as a computer, a television, a set-top box, a vehicle-mounted device, etc.

As shown in FIG. 15, an implementation of the present disclosure further provides an electronic device 60. The electronic device 60 comprises the above-mentioned memory system 40 provided by the implementation of the present disclosure. Specifically, the electronic device 60 may be any device that can store data, such as a mobile phone, a desktop computer, a tablet computer, a laptop computer, a server, a vehicle-mounted device, a wearable device, a mobile power supply, or the like.

The electronic device provided by the implementation of the present disclosure has the same beneficial effects as the above-mentioned memory system because of being provided with the memory system provided by the implementation of the present disclosure.

The semiconductor device and manufacturing method thereof, memory and memory system provided by the implementations of the present disclosure are introduced in detail above. Specific examples are used herein for elaborating the principle and implementations of the present disclosure. The description of the above implementations is merely used for helping to understand the method of the present disclosure and core idea thereof. Meanwhile, for those skilled in the an, alterations may be made to the implementations and the disclosure scope according to the idea of the present disclosure. In conclusion, the content of this specification should not be interpreted as a limitation to the present disclosure.

What is claimed is:

1. A semiconductor device, comprising:
a stack structure including alternately stacked dielectric layers and conductive layers, the conductive layers including a top select gate layer; and
channel holes penetrating through the stack structure,
wherein the top select gate layer is provided with a first top select gate isolation structure and a second top select gate isolation structure, the channel holes being located between the first top select gate isolation structure and the second top select gate isolation structure, and
the second top select gate isolation structure includes an insulation portion, the insulation portion being divided into a plurality of second top select gate isolation substructures.

2. The semiconductor device of claim 1, wherein the insulation portion of the second top select gate isolation structure is divided in a first direction into a plurality of strip-shaped second top select gate isolation substructures extending in a second direction perpendicular to the first direction.

3. The semiconductor device of claim 2, wherein the plurality of second top select gate isolation substructures are distributed side by side in the first direction, and the plurality of second top select gate isolation substructures have the same dimension in the first direction.

4. The semiconductor device of claim 2, wherein the plurality of second top select gate isolation substructures are distributed side by side in the first direction, and the plurality of second top select gate isolation substructures have different dimensions in the first direction.

5. The semiconductor device of claim 4, wherein dimensions of two outermost second top select gate isolation substructures of the plurality of second top select gate isolation substructures distributed side by side in the first direction are different from those of interior second top select gate isolation substructures between the two outermost second top select gate isolation substructures.

6. The semiconductor device of claim 4, wherein dimensions of the plurality of second top select gate isolation substructures distributed side by side in the first direction increase progressively or decrease progressively in the first direction.

7. The semiconductor device of claim 5, wherein the dimensions of the plurality of second top select gate isolation substructures distributed side by side in the first direction increase progressively or decrease progressively in a direction from the outermost second top select gate isolation substructures to the interior second top select gate isolation substructures.

8. The semiconductor device of claim 4, wherein a plurality of dimensions of the plurality of second top select gate isolation substructures distributed side by side in the first direction are alternately set in size in the first direction.

9. The semiconductor de-ice of claim 1, wherein the second top select gate isolation substructure includes a plurality of segmented structures that are misaligned up and down, left and right to form a plurality of windows.

10. A manufacturing method of a semiconductor device, comprising:
providing a stack layer;
forming alternately stacked dielectric layers and sacrificial layers on the stack layer, and replacing the sacrificial layers with conductive material to form conductive layers;
forming a top select gate layer on the conductive layer at the top of the stack layer to form a stack structure including the dielectric layers, the conductive layers, and the top select gate laver;
forming channel holes penetrating through the stack structure:
enabling the top select gate layer to be formed with a first top select gate isolation structure and a second top select gate isolation structure by using a patterning process, the channel holes being located between the first top select gate isolation structure and the second top select gate isolation structure;
dividing an insulation portion of the second top select gate isolation structure into a plurality of second top select gate isolation substructures by using an etching process; and
filling a conductive substance between two adjacent second top select gate isolation substructures to form corresponding conductive portion.

11. The manufacturing method of the semiconductor device of claim 10, wherein the dividing the insulation portion of the second top select gate isolation structure into the plurality of second top select gate isolation substructures comprises;
dividing the insulation portion of the second top select gate isolation structure in a first direction into a plurality of strip-shaped second top select gate isolation substructures extending in a second direction.

12. The manufacturing method of the semiconductor device of claim 11, further comprising:
dividing the insulation portion into a plurality of strip-shaped second top select gate isolation substructures that are distributed side by side in the first direction and have the same dimension in the first direction.

13. The manufacturing method of the semiconductor device of claim 11, further comprising:
dividing the insulation portion into a plurality of strip-shaped second top select gate isolation substructures that are distributed side by side in the first direction and have different dimensions in the first direction.

14. The manufacturing method of the semiconductor device of claim 10, further comprising:
forming the insulation portion to include a plurality of segmented structures that are misaligned, up and down, left and right to form a plurality of windows.

15. The manufacturing method of the semiconductor device of claim 10, further comprising:
removing the conductive substance between the two adjacent strip-shaped second top select gate isolation substructures.

16. The manufacturing method of the semiconductor device of claim 14, further comprising;
removing the conductive substance through the windows.

17. A memory system, comprising a memory and a controller coupled with the memory, the memory including a semiconductor device, the controller being used to control the memory to perform data writing and reading operations,
wherein the semiconductor device includes a stack structure and channel holes,
the stack structure includes alternately stacked dielectric layers and conductive layers, the conductive layers including a top select gate layer,
the channel holes penetrate through the stack structure,
the top select bate layer is provided with a first top select gate isolation structure and a second top select gate isolation structure, the channel holes being located between the first top select gate isolation structure and the second top select gate isolation structure, and
the second top select gate isolation structure includes an insulation portion, the insulation portion being divided into a plurality of second top select gate isolation substructures.
